(19) United States
(12) Patent Application Publication
(10) Pub. No.: US 2025/0247975 A1
(43) Pub. Date: Jul. 31, 2025

(54) DISPLAY DEVICE

(71) Applicant: LG Display Co., Ltd., Seoul (KR)

(72) Inventor: Sangwon Yoon, Seoul (KR)

(73) Assignee: LG Display Co., Ltd., Seoul (KR)

(21) Appl. No.: 18/923,611

(22) Filed: Oct. 22, 2024

(30) Foreign Application Priority Data
Jan. 31, 2024 (KR) 10-2024-0015013

(51) Int. Cl. H05K 5/02

(52) U.S. Cl. CPC H05K 5/0217

(57) ABSTRACT

A display device includes a display unit. The display device further includes a roller in which the display unit is wound or unwound and a flat surface portion, a curved surface portion extending from the flat surface portion, and a support unit disposed between the flat surface portion and the curved surface portion are included. The display device further includes a guide member which is supported by the roller to support the display unit. The display device further includes an elastic member which is supported by the support unit to apply an elastic force to the guide member in a direction away from the roller to connect the roller and the guide member.

### CROSS-REFERENCE TO RELATED APPLICATIONS

This application claims the priority of Korean Patent Application No. 10-2024-0015013 filed on Jan. 31, 2024, in the Korean Intellectual Property Office, the disclosure of which is incorporated herein by reference.

### BACKGROUND

### Technical Field

The present disclosure relates to a display device, and more particularly, to a rollable display device which is capable of displaying images even in a rolled state.

### Discussion of the Related Art

As display devices which are used for a monitor of a computer, a television, or a cellular phone, there are an organic light emitting display (OLED) device which is a self-emitting device and a liquid crystal display (LCD) device which requires a separate light source.

An applicable range of the display device is diversified to personal digital assistants as well as monitors of computers and televisions and a display device with a large display area and a reduced volume and weight is being studied.

Further, recently, a rollable display device which is manufactured by placing a display element and a wiring line on a flexible substrate such as plastic which is a flexible material so as to be capable of displaying images even in a rolled state is getting attention as a next generation display device.

### SUMMARY

Accordingly, embodiments of the present disclosure are directed to a display device that substantially obviates one or more of the problems due to limitations and disadvantages of the related art.

An aspect of the present disclosure is to provide a display device which minimizes a damage of a display unit due to repeated winding and unwinding.

Another aspect of the present disclosure is to provide a display device which minimizes stress applied to the display unit when the display unit is wound.

Still another aspect of the present disclosure is to provide a display device which reduces a risk of a crack generated in the display unit by suppressing the display unit from being excessively bent in a boundary area of a flat surface portion and a curved surface portion when the display unit is wound.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a display unit, a roller in which the display unit is wound or unwound and a flat surface portion, a curved surface portion extending from the flat surface portion, and a support unit disposed between the flat surface portion and the curved surface portion are included; a guide member which is supported by the roller to support the display unit; and an elastic member which is supported by the support unit to apply an elastic force to the guide member in a direction away from the roller to connect the roller and the guide member.

Other detailed matters of the exemplary embodiments are included in the detailed description and the drawings.

According to the present disclosure, a guide member which supports the display unit is disposed between a flat surface portion and a curved surface portion of a roller in which the display unit is wound or unwound to support the display unit to be wound with a larger curvature radius in a boundary area between the flat surface portion and the curved surface portion of the roller. By doing this, the crack defect may be improved.

Further, according to the present disclosure, a guide member is disposed on the roller to support the display unit to be gently bent to minimize the damage on the display unit which is wound on the roller to be excessively bent.

Further, according to the present disclosure, a stress distribution is concentrated in the center portion of the display unit and the stress is minimized in both edge portions of the display unit while supporting a center portion and both edges of the display unit using a plurality of guide members. Therefore, a crack generated in a GIP area which has a relatively low rigidity is effectively suppressed.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIGS. 1A and 1B are perspective views of a display device according to an exemplary embodiment of the present disclosure;

FIG. 2 is a perspective view of a display device according to an exemplary embodiment of the present disclosure;

FIG. 3 is a cross-sectional view of a display device according to an exemplary embodiment of the present disclosure;

FIG. 4 is a front surface view of a display unit of a display device according to an exemplary embodiment of the present disclosure;

FIG. 5 is a cross-sectional view of a display unit of a display device according to an exemplary embodiment of the present disclosure;

FIG. 6 is a side surface view of a display device according to an exemplary embodiment of the present disclosure;

FIG. 7 is a side surface view illustrating that a roller unit of a display device according to an exemplary embodiment of the present disclosure is disassembled;

FIG. 8 is a rear surface view of a roller unit of a display device according to an exemplary embodiment of the present disclosure;

FIG. 9 is a side surface view illustrating that a guide assembly provided in a roller unit of a display device according to an exemplary embodiment of the present disclosure is disassembled;

FIG. 10 is a rear surface view illustrating that a coupler provided in a roller unit of a display device according to an exemplary embodiment of the present disclosure is disassembled;

FIG. 11 is a plan surface view illustrating that a coupler provided in a roller unit of a display device according to an exemplary embodiment of the present disclosure is disassembled;

FIG. 12 is a view illustrating a coupled state of a coupler and an elastic member provided in a roller unit of a display device according to an exemplary embodiment of the present disclosure;

FIG. 13 is a view illustrating a method of coupling a guide member and an elastic member provided in a roller unit of a display device according to an exemplary embodiment of the present disclosure;

FIG. 14A is a view schematically illustrating a state that a roller unit of a display device according to an exemplary embodiment of the present disclosure is not in contact with a display unit;

FIG. 14B is a view schematically illustrating a state that a roller unit of a display device according to an exemplary embodiment of the present disclosure is in contact with a display unit;

FIG. 15 is a side surface view illustrating a state that a roller unit of a display device according to an exemplary embodiment of the present disclosure is in contact with a display unit;

FIG. 16 is a view schematically illustrating a display device according to another exemplary embodiment of the present disclosure;

FIG. 17A is a side surface view of a roller unit of a display device according to an exemplary embodiment;

FIG. 17B is a simulation image illustrating a stress distribution applied to a display unit when a display unit of a display device according to an exemplary embodiment is wound around a roller unit;

FIG. 18A is a side surface view of a roller unit of a display device according to a comparative embodiment; and

FIG. 18B is a simulation image illustrating a stress distribution applied to a display unit when a display unit of a display device according to a comparative embodiment is wound around a roller unit.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly” is not used.

When an element or layer is referred to as being “on” another element or layer, it may be directly on the other element or layer, or intervening elements or layers may be present therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawings are illustrated for convenience of explanation, and are not limited to the size and the thickness of the component illustrated in embodiments of the present disclosure.

The features of various embodiments of the present disclosure can be partially or entirely coupled to or combined with each other and can be interlocked and operated in technically various ways, and respective embodiments can be carried out independently of or in association with each other.

Hereinafter, embodiments of the present disclosure will be described in detail with reference to the drawings.

A rollable display device may be referred to as a display device which is capable of displaying images even though the display device is rolled. The rollable display device may have a high flexibility as compared with a general display device of the related art. Depending on whether to use a rollable display device, a shape of the rollable display device may freely vary. Specifically, when the rollable display device is not used, the rollable display device is rolled to be stored with a reduced volume. In contrast, when the rollable display device is used, the rolled rollable display device is unrolled to be used.

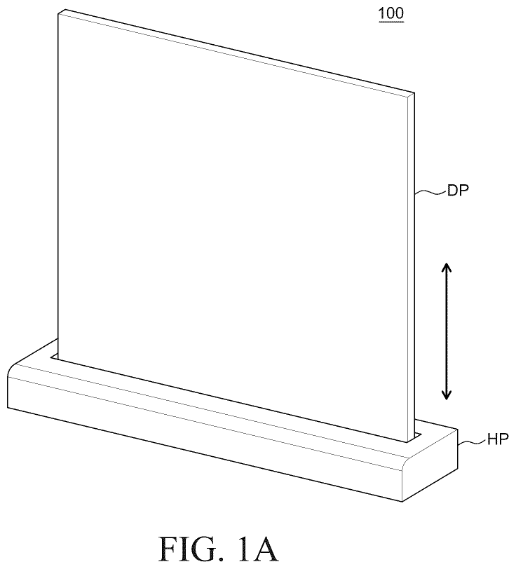

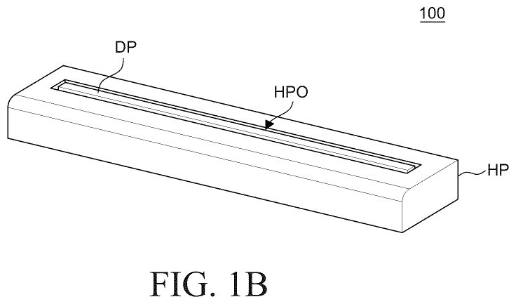

FIGS. 1A and 1B are perspective views of a display device according to an exemplary embodiment of the present disclosure. Referring to FIGS. 1A and 1B, a display device 100 according to an exemplary embodiment of the present disclosure includes a display unit DP and a housing unit HP.

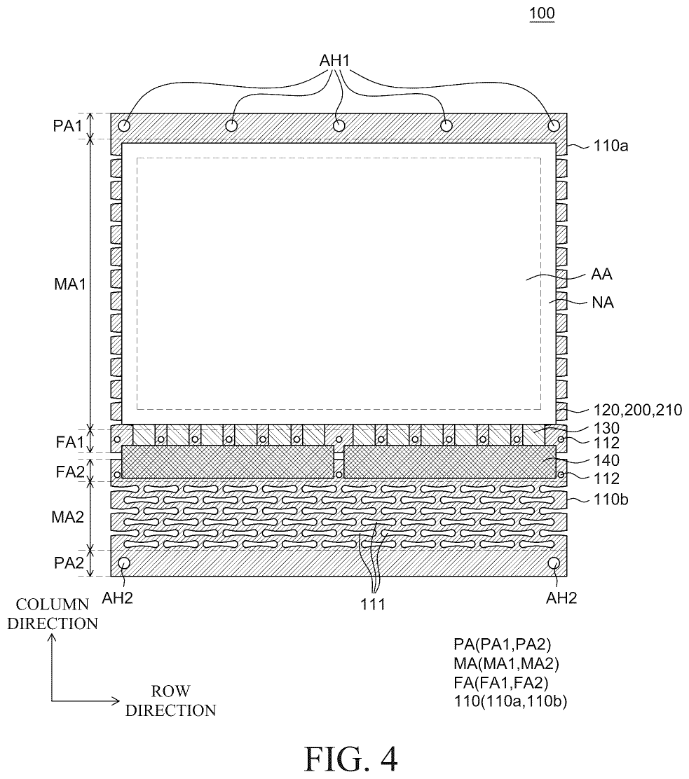

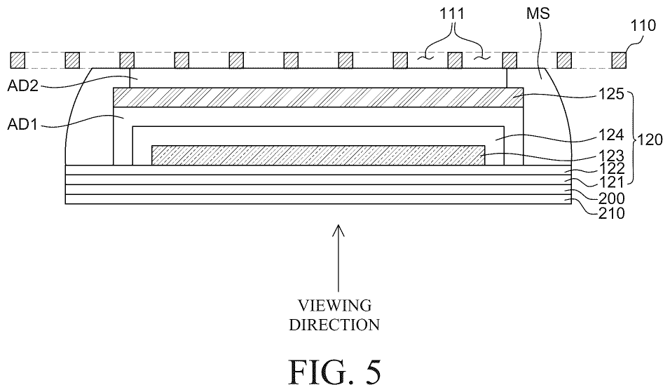

The display unit DP is a configuration for displaying images to a user and for example, in the display unit DP, a display element and a circuit, a wiring line, and a component for driving the display element may be disposed. In this case, since the display device 100 according to the exemplary embodiment of the present disclosure is a rollable display device, the display unit DP may be configured to be wound or unwound. For example, the display unit DP may be formed of a display panel and a back cover each having a flexibility to be wound or unwound. The display unit DP will be described below in more detail with reference to FIGS. 4 and 5.

The housing unit HP is a case in which the display unit DP is accommodated. The display unit DP may be wound to be accommodated in the housing unit HP and the display unit DP may be unwound to be disposed at the outside of the housing unit HP.

The housing unit HP has an opening HPO through which the display unit DP moves to the inside and the outside of the housing unit HP. The display unit DP may move in a vertical direction by passing through the opening HPO of the housing unit HP.

In the meantime, the display unit DP of the display device 100 may be switched from a fully unwound state to a fully wound state or from a fully wound state to a fully unwound state.

FIG. 1A illustrates a fully unwound state of the display unit DP of the display device 100 and the fully unwound display unit DP of the display device 100 is disposed at the outside of the housing unit HP. That is, in order for a user to watch images through the display device 100, when the display unit DP is unwound to be disposed at the outside of the housing unit HP as much as possible and may not be further unwound any more, it may be defined as a fully unwound state.

FIG. 1B illustrates the display unit DP of the display device 100 which is fully wound and in the fully wound state, the display unit DP of the display device 100 is accommodated in the housing unit HP and may not be further wound. That is, when the user does not watch the images through the display device 100, it is advantageous from the viewpoint of an outer appearance that the display unit DP is not disposed at the outside of the housing unit HP. Therefore, when the display unit DP is wound to be accommodated in the housing unit HP, it may be defined as a fully wound state. Further, when the display unit DP is in a fully wound state to be accommodated in the housing unit HP, a volume of the display device 100 is reduced so that the display device 100 may be easily carried.

In the meantime, in order to switch the display unit DP to a fully unwound state or a fully wound state, a driving unit which winds or unwinds the display unit DP is disposed.

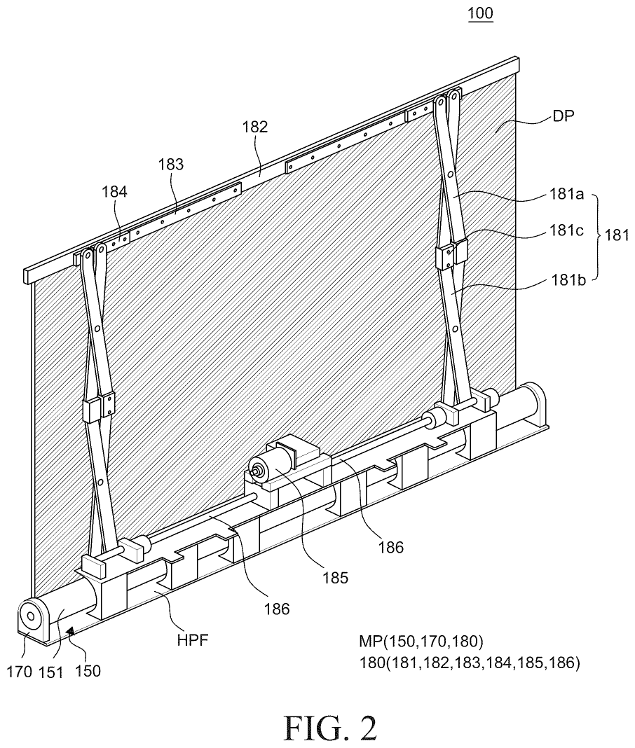

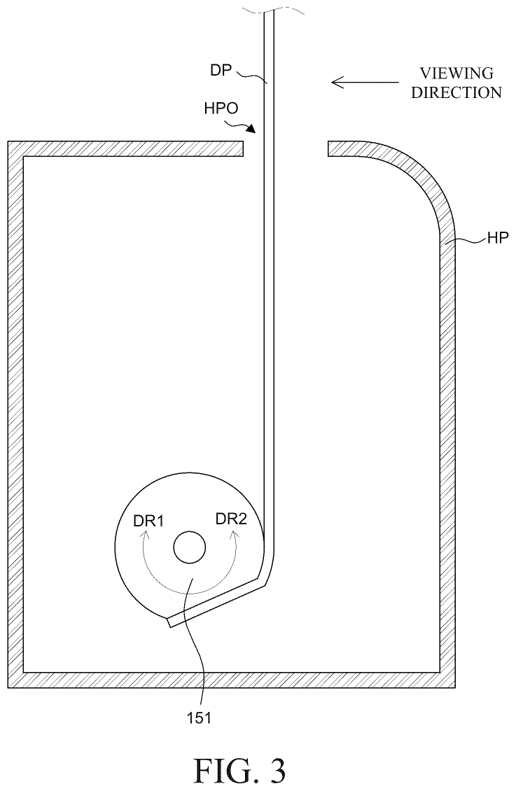

FIG. 2 is a perspective view of a display device according to an exemplary embodiment of the present disclosure and FIG. 3 is a cross-sectional view of a display device according to an exemplary embodiment of the present disclosure. FIG. 3 is a schematic cross-sectional view for explaining a roller 151 and a display unit DP of a display device 100 according to an exemplary embodiment of the present disclosure. For the convenience of description, in FIG. 3, only a housing unit HP, a roller 151, and a display unit DP are illustrated.

First, referring to FIG. 2, the driving unit MP includes a roller unit 150, a roller support member 170, and a lifting unit 180.

The roller unit 150 rotates in a clockwise direction or a counterclockwise direction to wind or unwind the display unit DP fixed to the roller unit 150. The roller unit 150 includes a roller 151 which is rotatably supported to the roller support member 170. The roller support member 170 is disposed on a bottom surface HPF of the housing unit HP to support the roller 151 to be spaced apart from the bottom surface HPF of the housing unit HP.

The roller 151 is a member around which the display unit DP is wound. The roller 151 may be, for example, formed to have a cylindrical shape. A lower edge of the display unit DP may be fixed to the roller 151. When the roller 151 rotates, the display unit DP which is fixed to the roller 151 through the lower edge may be wound around the roller 151. In contrast, when the roller 151 rotates in an opposite direction, the display unit DP which is wound around the roller 151 may be unwound from the roller 151.

Referring to FIG. 3, the roller 151 may be formed to have a cylindrical shape in which at least a part of an outer circumferential surface has a flat surface and the most part has a curved surface. Even though the roller 151 may have entirely a cylindrical shape, but a part thereof may be formed of a flat surface. The flat surface part of the roller 151 may be a part in which at least one flexible film 130 and the printed circuit board 140 of the display unit DP are seated. However, the roller 151 may have a completely cylindrical shape or an arbitrary shape which may wind the display unit DP, but is not limited thereto.

The lifting unit 180 moves the display unit DP in a vertical direction in accordance with the driving of the roller unit 150. The lifting unit 180 includes a link unit 181, a head bar 182, a slide rail 183, a slider 184, a motor 185, and a rotary unit 186.

The link unit 181 of the lifting unit 180 includes a plurality of links 181a and 181b and a hinge unit 181c which connects the plurality of links 181a and 181b to each other. Specifically, the plurality of links 181a and 181b includes a first link 181a and a second link 181b and the first link 181a and the second link 181b cross each other in the form of scissors to be rotatably fastened by means of the hinge unit 181c. When the link unit 181 moves in the vertical direction, the plurality of links 181a and 181b rotates to be far away from each other or close to each other.

The head bar 182 of the lifting unit 180 is fixed to an uppermost end of the display unit DP. The head bar 182 is coupled to the link unit 181 to move the display unit DP in the vertical direction in accordance with the rotation of the plurality of links 181a and 181b of the link unit 181. That is, the display unit DP may move in a vertical direction by the head bar 182 and the link unit 181.

The head bar 182 covers only a part of a surface which is adjacent to an uppermost edge of the display unit DP so as not to block an image displayed on the front surface of the display unit DP. The display unit DP and the head bar 182 may be fixed by a screw, but are not limited thereto.

The slide rail 183 of the lifting unit 180 provides a movement path of the plurality of links 181a and 181b. Some of the plurality of links 181a and 181b is rotatably fastened with the slide rail 183 so that the motion is guided along a trajectory of the slide rail 183. Some of the plurality of links 181a and 181b is fastened with the slider 184 which is movably provided along the slide rail 183 to move along a trajectory of the slide rail 183.

The motor 185 is connected to a power generating unit, such as a separate external power source or a built-in battery, to be supplied with the power. The motor 185 generates a torque to provide a driving force to the rotary unit 186.

The rotary unit 186 is connected to the motor 185 to convert a rotational motion from the motor 185 into a linear reciprocating motion. That is, the rotational motion of the motor 185 may be converted into the linear reciprocating motion of a structure fixed to the rotary unit 186. For example, the rotary unit 186 may be implemented by a ball screw including a shaft and a nut which is fastened with the shaft, but is not limited thereto.

The motor 185 and the rotary unit 186 interwork with the link unit 181 to lift and lower the display unit DP. The link unit 181 is provided with a link structure to receive the driving force from the motor 185 and the rotary unit 186 to repeatedly perform the folding or unfolding operation.

Specifically, as the motor 185 is driven, the structure of the rotary unit 186 may perform the linear motion. That is, a part of the rotary unit 186 to which one end of the second link 181b is coupled may perform the linear motion. Therefore, one end of the second link 181b moves toward the motor 185 and the plurality of links 181a and 181b is folded so that the height of the link unit 181 may be reduced. Further, while the plurality of links 181a and 181b are folded, the head bar 182 coupled to the first link 181a is also lowered and one end of the display unit DP coupled to the head bar 182 is also lowered.

Accordingly, when the display unit DP is fully wound around the roller 151, the link unit 181 of the lifting unit 180 maintains a folded state. That is, when the display unit DP is fully wound around the roller 151, the lifting unit 180 may have a smallest height. When the display unit DP is fully unwound, the link unit 181 of the lifting unit 180 maintains a stretched state. That is, when the display unit DP is fully unwound, the lifting unit 180 may have a largest height.

In the meantime, when the display unit DP is wound, the roller 151 may rotate and the display unit DP may be wound around the roller 151. Referring to FIG. 3, a lower edge of the display unit DP is coupled to the roller 151. Further, when the roller 151 rotates in a first direction DR1, that is, a clockwise direction, the display unit DP may be wound while a rear surface of the display unit DP is in close contact with a front surface of the roller 151.

When the display unit DP is unwound, the roller 151 may rotate and the display unit DP may be unwound from the roller 151. For example, referring to FIG. 3, when the roller 151 rotates in a second direction DR2, that is, in a counterclockwise direction, the display unit DP which is wound around the roller 151 is unwound from the roller 151 to be disposed at the outside of the housing unit HP.

In some exemplary embodiments, a driving unit MP having another structure other than the above-described driving unit MP may be applied to the display device 100. That is, as long as the display unit DP is wound and unwound, the above-described configuration of the roller unit 150 and the lifting unit 180 may be modified, some configurations may be omitted, or another configuration may be further added.

FIG. 4 is a front surface view of a display unit of a display device according to an exemplary embodiment of the present disclosure. FIG. 5 is a cross-sectional view of a display unit of a display device according to an exemplary embodiment of the present disclosure.

Referring to FIG. 4, the display unit DP includes a back cover 110, a display panel 120, a flexible film 130, a printed circuit board 140, a barrier film 200, and a polarizer 210.

The display panel 120 is a panel for displaying images to a user. The display panel 120 may include a display element which displays images, a driving element which drives the display element, and wiring lines which transmit various signals to the display element and the driving element. The display element may be defined in different ways depending on a type of the display panel 120. For example, when the display panel 120 is an organic light emitting display panel, the display element may be an organic light emitting diode which includes an anode, an organic light emitting layer, and a cathode. For example, when the display panel 120 is a liquid crystal display panel, the display element may be a liquid crystal display element. Hereinafter, even though the display panel 120 is assumed as an organic light emitting display panel, the display panel 120 is not limited to the organic light emitting display panel. Further, since the display device 100 according to the exemplary embodiment of the present disclosure is a rollable display device, the display panel 120 may be implemented as a flexible display panel to be wound around or unwound from the roller 151.

The display panel 120 includes an active area AA and a non-active area NA.

The active area AA is an area where images are displayed in the display panel 120. In the active area AA, a plurality of pixels which includes a plurality of sub pixels and a circuit for driving the plurality of sub pixels may be disposed. The plurality of sub pixels is minimum units which configure the active area AA and a display element may be disposed in each of the plurality of sub pixels. For example, an organic light emitting diode which includes an anode, an organic light emitting layer, and a cathode may be disposed in each of the plurality of sub pixels, but it is not limited thereto. Further, a circuit for driving the plurality of sub pixels may include a driving element and a wiring line. For example, the circuit may be configured by a thin film transistor, a storage capacitor, a gate line, and a data line, but is not limited thereto.

The non-active area NA is an area where no image is displayed. The non-active area NA may extend from the active area AA. In the non-active area NA, various wiring lines and circuits for driving the organic light emitting diode of the active area AA are disposed. For example, in the non-active area NA, a link line which transmits signals to the plurality of sub pixels and circuits of the active area AA or a driving IC such as a gate driver IC or a data driver IC may be disposed, but it is not limited thereto.

The barrier film 200 and the polarizer 210 may be disposed on the display panel 120.

The flexible film 130 is a film in which various components are disposed on a base film having a malleability and supplies a signal to the plurality of sub pixels and the circuits of the active area AA and is electrically connected to the display panel 120. The flexible film 130 is disposed at one end of the non-active area NA of the display panel 120 to supply a power voltage or a data voltage to the plurality of sub pixels and the circuits of the active area AA. The number of flexible films 130 illustrated in FIG. 4 is illustrative and the number of flexible films 130 may vary depending on the design, but is not limited thereto.

In the meantime, for example, a driving IC such as a gate driver IC or a data driver IC may be disposed on the flexible film 130. The driving IC is a component which processes data for displaying images and a driving signal for processing the data. The driving IC may be disposed in a chip on glass (COG), a chip on film (COF), or a tape carrier package (TCP) manner depending on a mounting method. However, for the convenience of description, it is described that the driving IC is mounted on the flexible film 130 by a chip on film manner, but is not limited thereto.

The printed circuit board 140 is disposed at one end of the flexible film 130 to be connected to the flexible film 130. The printed circuit board 140 is a component which supplies signals to the driving IC. The printed circuit board 140 supplies various signals such as a driving signal or a data signal to the driving IC. Various components may be disposed on the printed circuit board 140. For example, a timing controller and a power source unit may be disposed on the printed circuit board 140. In the meantime, even though two printed circuit boards 140 are illustrated in FIG. 4, the number of printed circuit boards 140 may vary depending on the design and is not limited thereto.

In the meantime, even though not illustrated in FIG. 4, an additional printed circuit board which is connected to the printed circuit board 140 may be further disposed. For example, the printed circuit board 140 may be referred to as a source printed circuit board S-PCB on which the data driver is mounted and the additional printed circuit board connected to the printed circuit board 140 may be referred to as a control printed circuit board C-PCB on which a timing controller is mounted. The additional printed circuit board may be disposed in the roller 151 or disposed in the housing unit HP at the outside of the roller 151.

The back cover 110 is disposed on rear surfaces of the display panel 120, the flexible film 130, and the printed circuit board 140 to support the display panel 120, the flexible film 130, and the printed circuit board 140. A size of the back cover 110 may be larger than a size of the display panel 120. The back cover 110 may protect other configurations of the display unit DP from the outside. Even though the back cover 110 is formed of a material having a rigidity, at least a part of the back cover 110 may have a flexibility to be wound or unwound together with the display panel 120. For example, the back cover 110 may be formed of a metal material such as steel use stainless (SUS) or invar or plastic. However, as long as a material of the back cover 110 satisfies physical conditions such as a thermal strain amount, a radius of curvature, and a rigidity, various materials may be used, and is not limited thereto.

The back cover 110 includes a plurality of support areas PA, a fixing area FA, and a plurality of malleable areas MA. The plurality of support areas PA and the fixing area FA are areas where a plurality of openings 111 is not disposed and the plurality of malleable areas MA is areas where a plurality of openings 111 is disposed. Specifically, a first support area PA1, a first malleable area MA1, fixing areas FA1 and FA2, a second malleable area MA2, and a second support area PA2 are sequentially disposed from an uppermost end of the back cover 110.

The first support area PA1 of the back cover 110 is an uppermost area of the back cover 110 and is fastened with a head bar 182. In the first support area PA1, first fastening holes AH1 to be fastened with the head bar 182 are disposed. In this case, the first support area PA1 may be fastened with the head bar 182 by means of a screw, but is not limited thereto. As the first support area PA1 is fastened with the head bar 182, when the link unit 181 which is fastened with the head bar 182 is lifted or lowered, the back cover 110 is also lifted and lowered together with the display panel 120 attached to the back cover 110. Even though five first fastening holes AH1 are illustrated in FIG. 4, the number of first fastening holes AH1 is not limited thereto. Further, even though in FIG. 4, it has been described that the back cover 110 is fastened with the head bar 182 using the first fastening holes AH1, it is not limited thereto and the back cover 110 and the head bar 182 may be fastened with each other without using a separate fastening hole.

The first malleable area MA1 is an area extending from the first support area PA1 to a lower side of the back cover 110. The first malleable area MA1 is an area in which a plurality of openings 111 is disposed and the display panel 120 is attached.

When the display unit DP is wound around the roller 151 to be accommodated in the housing unit HP, the first malleable area MA1 of the back cover 110 and the lower end portion and a center portion of the display panel 120 which are attached to the first malleable area MA1 may be wound around the roller 151. In this case, in the first malleable area MA1 of the back cover 110, the plurality of openings 111 is provided so that the first malleable area MA1 may have a high flexibility and may be easily wound around the roller 151 together with the display panel 120.

The fixing area FA is an area extending from the first malleable area MA1 to the lower side of the back cover 110. In order to protect the flexible film 130 and the printed circuit board 140, the fixing area FA may allow the flexible film 130 and the printed circuit board 140 to be wound around the roller 851 in a flat surface shape, rather than in a curved surface shape. Further, a part of the roller 151 may be formed to be flat surface shape, correspondingly to the fixing area FA.

In the fixing area FA, a plurality of fixing holes 112 is disposed. The plurality of fixing holes 112 is disposed between the flexible films 130 to more stably fix the flexible film 130 and the printed circuit board 140 to the fixing area FA. In the meantime, the number of the plurality of fixing holes 112 illustrated in FIG. 4 is illustrative and the number of the plurality of fixing holes 112 may be determined based on the number of printed circuit board 140 and the number of flexible films 130.

In the meantime, the back cover 110 is configured to be divided into a first back cover 110a and a second back cover 110b, between the plurality of fixing holes 112 of the first fixing area FA1 and the plurality of fixing holes 112 of the second fixing area FA2. That is, the first back cover 110a includes a first support area PA1, a first malleable area MA1, and a first fixing area FA1 and the second back cover 110b includes a second fixing area FA2, a second malleable area MA2, and the second support area PA2. However, it is not limited thereto and the back cover 110 may be integrally formed.

The second malleable area MA2 is an area extending from the fixing area FA to a lower side of the back cover 110. Further, a plurality of openings 111 is disposed in the second malleable area MA2.

The second malleable area MA2 extends to dispose the active area AA of the display panel 120 at the outside of the housing unit HP. For example, when the back cover 110 and the display panel 120 are fully unwound, the second support area PA2 of the back cover 110 which is fixed to the roller 151 to the fixing area FA to which the flexible film 130 and the printed circuit board 140 are attached may be disposed in the housing unit HP. The first malleable area MA1 and the fixing area FA to which the display panel 120 is attached may be disposed at the outside of the housing unit HP. In this case, when a length from the second support area PA2 fixed to the roller 151 to the second malleable area MA2 and the fixing area FA is smaller than a length from the second support area PA2 to the opening HPO of the housing unit HP, a part of the first malleable area MA1 to which the display panel 120 is attached may be disposed in the housing unit HP. Therefore, since a part of the lower end of the active area AA of the display panel 120 is disposed in the housing unit HP, it may be difficult to watch images. Therefore, the length from the second support area PA2 fixed to the roller 151 to the second malleable area MA2 and the fixing area FA may be designed to be equal to the length from the second support area PA2 fixed to the roller 151 to the opening HPO of the housing unit HP.

The second support area PA2 of the back cover 110 is a lowermost area of the back cover 110 and is fastened with the roller 151 to be fixed to the roller 151. The second support area PA2 may include second fastening holes AH2 to be fastened with the roller 151. In this case, the second support area PA2 may be fastened with the roller 151 by means of a screw, but is not limited thereto. As the second support area PA2 is fastened with the roller 151, the back cover 110 may be wound around or unwound from the roller 151 by the rotation of the roller 151. Even though two second fastening holes AH2 are illustrated in FIG. 4, the number of second fastening holes AH2 is not limited thereto. Further, even though in FIG. 4, it has been described that the back cover 110 is fastened with the roller 151 using the second fastening holes AH2, it is not limited thereto. The back cover 110 and the roller 151 may be fixed to each other without using a separate fastening hole.

The malleable area MA of the back cover 110 is an area which is wound around or unwound from the roller 151 together with the display panel 120. The malleable area MA may overlap at least the display panel 120 among other configurations of the display unit DP.

A plurality of openings 111 is disposed in the malleable area MA of the back cover 110. When the display unit DP is wound or unwound, the plurality of openings 111 may be deformed by a stress which is applied to the display unit DP. Specifically, when the display unit DP is wound or unwound, the malleable areas MA of the back cover 110 may be deformed as the plurality of openings 111 contracts or expands. Further, as the plurality of openings 111 contracts or expands, a slip phenomenon of the display panel 120 disposed on the malleable area MA of the back cover 110 is minimized so that the stress which is applied to the display panel 120 may be minimized.

Referring to FIG. 4, the plurality of openings 111 is disposed alternately with a plurality of openings 111 in adjacent rows. For example, a plurality of openings 111 disposed in one row is disposed alternately with a plurality of openings 111 disposed in a row adjacent to the row. Specifically, a center of the plurality of openings 111 disposed in an odd-numbered row and a center of the plurality of openings 111 disposed in an even-numbered row are alternately disposed and for example, may be alternately disposed by a half of a width in a row direction of the openings 111. However, the placement of the plurality of openings 111 illustrated in FIG. 4 is just an example, and is not limited thereto.

In this case, in the first support area PA1 and the second support area PA2, the plurality of openings 111 as formed in the malleable area MA is not provided. That is, in the first support area PA1 and the second support area PA2, only the first fastening holes AH1 and the second fastening holes AH2 are provided, but the plurality of openings 111 as formed in the malleable area MA is not provided. Further, the first fastening holes AH1 and the second fastening holes AH2 have different shapes from that of the plurality of openings 111. The first support area PA1 and the second support area PA2 which are fixed to the head bar 182 and the roller 151, respectively, need to be more rigid than the malleable area MA. Specifically, as the first support area PA1 and the second support area PA2 have the rigidity, the first support area PA1 and the second support area PA2 may be firmly fixed to the head bar 182 and the roller 151. Therefore, the display unit DP is fixed to the roller 151 and the head bar 182 of the driving unit MP to be moved to the inside or the outside of the housing unit HP in accordance with the operation of the driving unit MP.

In the display device 100 according to the exemplary embodiment of the present disclosure, the back cover 110 with the plurality of openings 111 provided therein is disposed on the rear surface of the display panel 120 to support and protect the display panel 120. The back cover 110 is formed of a metal material to have a rigidity and the plurality of openings 111 is provided in the malleable area MA of the back cover 110 where the display panel 120 is disposed so that the flexibility of the back cover 110 may be enhanced. Therefore, in a fully unwound state in which the display unit DP of the display device 100 is disposed at the outside of the housing unit HP, the back cover 110 which is formed of a rigid material to have a high rigidity may support the display panel 120 to be flatly spread. In contrast, in a fully wound state in which the display unit DP of the display device 100 is accommodated in the housing unit HP, the back cover 110 having a high flexibility due to the plurality of openings 111 is wound around the roller 151 together with the display panel 120 to be accommodated.

Further, in the display device 100 according to the exemplary embodiment of the present disclosure, the back cover 110 is configured by the first back cover 110a and the second back cover 110b which are separated to form the back cover 110 so as to correspond to various sizes of the display panel 120. As the size of the display device 100 is gradually increased, the size of the display panel 120 is also increased. In this case, the back cover 110 needs to be larger than the size of the display panel 120, a single back cover 110 is necessarily manufactured to be large. However, when the single back cover 110 is manufactured to correspond to the large size display device, there may be a big difficulty in the manufacturing process. Therefore, in the display device 100 according to the exemplary embodiment of the present disclosure, the back cover 110 is configured by the first back cover 110a and the second back cover 110b to use the first back cover 110a and the second back cover 110b having a smaller size than the display device 100. Even though it is not illustrated in the drawing, the first back cover 110a and the second back cover 110b may be fixed by a separate fixing member.

Referring to FIG. 5, the back cover 110 is disposed on the rear surface of the display panel 120 and the barrier film 200 and the polarizer 210 are disposed on the front surface of the display panel 120. Here, the front surface of the display panel 120 may refer to a surface corresponding to a viewing direction and the rear surface of the display panel 120 may refer to a surface opposite to the viewing direction.

The display panel 120 includes a substrate 121, a buffer layer 122, a pixel unit 123, an encapsulation layer 124, and an encapsulation substrate 125.

The substrate 121 is a base member which supports various components of the display panel 120 and may be configured by an insulating material. The substrate 121 may be formed of a material having a flexibility to allow the display panel 120 to be wound or unwound and for example, may be formed of a plastic material such as polyimide (PI).

The buffer layer 122 may suppress moisture and/or oxygen which penetrates from the outside of the substrate 121 from being spread. The buffer layer 122 may be configured by a single layer or a double layer of silicon oxide (SiOx) and silicon nitride (SiNx), but is not limited thereto.

The pixel unit 123 includes a plurality of organic light emitting diodes and a circuit for driving the organic light emitting diodes. The pixel unit 123 may be an area corresponding to the active area AA. The organic light emitting diode may include an anode, an organic light emitting layer, and a cathode.

The anode may supply holes to the organic light emitting layer and be formed of a conductive material having a high work function. For example, the anode may be formed of tin oxide (TO), indium tin oxide (ITO), indium zinc oxide (IZO), or indium zinc tin oxide (ITZO), but is not limited thereto.

The organic light emitting layer is supplied with holes from the anode and supplied with electrons from the cathode to emit light. The organic light emitting layer may be formed of a red organic light emitting layer, a green organic light emitting layer, a blue organic light emitting layer, and a white organic light emitting layer depending on a color of light emitted from the organic light emitting layer. In this case, when the organic light emitting layer is a white organic light emitting layer, color filters having various colors may be additionally disposed.

The cathode may supply electrons to the organic light emitting layer and be formed of a conductive material having a low work function. For example, the cathode may be formed of any one or more selected from a group consisting of metals, such as magnesium (Mg), silver (Ag), and aluminum (Al), and an alloy thereof, but is not limited thereto.

In the meantime, the display panel 120 may be configured by a top emission type or a bottom emission type, depending on an emission direction of light which is emitted from the organic light emitting diode.

According to the top emission type, light emitted from the organic light emitting diode is emitted to the top of the substrate 121 equipped with the organic light emitting diode. In the case of the top emission type, a reflective layer may be provided below the anode to allow the light emitted from the organic light emitting diode to travel to the upper portion of the substrate 121, that is, toward the cathode.

According to the bottom emission type, light emitted from the organic light emitting diode is emitted to a lower portion of the substrate 121 on which the organic light emitting diode is provided. In the case of the bottom emission type, the anode may be formed only of a transparent conductive material and the cathode may be formed of the metal material having a high reflectance to allow the light emitted from the organic light emitting diode to travel to the lower portion of the substrate 121.

Hereinafter, for the convenience of description, the description will be made by assuming that the display device 100 according to an exemplary embodiment of the present disclosure is a bottom emission type display device, but it is not limited thereto.

A circuit for driving the organic light emitting diode is disposed in the pixel unit 123. The circuit may be formed of a thin film transistor, a storage capacitor, a gate line, a data line, and a power line, but it may vary in various forms depending on the design of the display device 100.

The encapsulation layer 124 which covers the pixel unit 123 is disposed on the pixel unit 123. The encapsulation layer 124 seals the organic light emitting diode of the pixel unit 123. The encapsulation layer 124 may protect the organic light emitting diode of the pixel unit 123 from moisture, oxygen, and impacts of the outside. The encapsulation layer 124 may be formed by alternately laminating a plurality of inorganic layers and a plurality of organic layers. For example, the inorganic layer may be formed of an inorganic material such as silicon nitride (SiNx), silicon oxide (SiOx), and aluminum oxide (AlOx) and the organic layer may use epoxy or acrylic-based polymer, but they are not limited thereto.

The encapsulation substrate 125 is disposed on the encapsulation layer 124. The encapsulation substrate 125 protects the organic light emitting diode of the pixel unit 123 together with the encapsulation layer 124. The encapsulation substrate 125 may protect the organic light emitting diode of the pixel unit 123 from moisture, oxygen, and impacts of the outside. The encapsulation substrate 125 may be formed of a metal material, which has a high corrosion resistance and is easily processed in the form of a foil or a thin film, such as aluminum (Al), nickel (Ni), chromium (Cr), and an alloy material of iron (Fe) and nickel. Therefore, as the encapsulation substrate 125 is provided with a metal material, the encapsulation substrate 125 may be implemented by an ultra-thin film and have a high resistance against external impacts and scratches.

A first adhesive layer AD1 may be disposed between the encapsulation layer 124 and the encapsulation substrate 125. The first adhesive layer AD1 may bond the encapsulation layer 124 and the encapsulation substrate 125 to each other. The first adhesive layer AD1 is formed of a material having adhesiveness and may be a thermosetting or natural curable type adhesive. For example, the first adhesive layer AD1 may be formed of an optical clear adhesive (OCA) or a pressure sensitive adhesive (PSA), but is not limited thereto.

In the meantime, the first adhesive layer AD1 may be disposed so as to enclose the encapsulation layer 124 and the pixel unit 123. That is, the pixel unit 123 may be sealed by the buffer layer 122 and the encapsulation layer 124 and the encapsulation layer 124 and the pixel unit 123 may be sealed by the buffer layer 122 and the first adhesive layer AD1. The first adhesive layer AD1 may protect the organic light emitting diode of the pixel unit 123 from moisture, oxygen, and impacts of the outside together with the encapsulation layer 124 and the encapsulation substrate 125. In this case, the first adhesive layer AD1 may further include an absorbent. The absorbent may be particles having hygroscopicity and absorb moisture and oxygen from the outside to minimize permeation of the moisture and oxygen into the pixel unit 123.

The back cover 110 is disposed on the encapsulation substrate 125. The back cover 110 is disposed to be in contact with the encapsulation substrate 125 of the display panel 120 to protect the display panel 120. In order to protect the display panel 120, the back cover 110 may be formed of a material having a rigidity.

A second adhesive member AD2 is disposed between the encapsulation substrate 125 and the back cover 110. The second adhesive member AD2 may bond the encapsulation substrate 125 and the back cover 110. The second adhesive member AD2 is formed of a material having adhesiveness and may be a thermosetting or natural curable type adhesive. For example, the adhesive member AD2 may be formed of an optical clear adhesive (OCA) or a pressure sensitive adhesive (PSA), but is not limited thereto.

A micro-seal MS may be disposed on the side surface of the display panel 120. The micro-seal MS may be disposed between the substrate 121 and the back cover 110 to enclose a side surface of the display panel 120. That is, the side portion of the display panel 120 may be sealed by the micro-seal MS. The micro-seal MS may protect the display panel 120 from moisture, oxygen, and shocks from the outside. The micro-seal MS may be formed of a photo-curable acrylic resin, but is not limited thereto.

The barrier film 200 is disposed on the front surface of the display panel 120. The barrier film 200 may protect the display panel 120 from impacts, moisture, and heat from the outside. The barrier film 200 may be configured by a polymer resin having a characteristic which is light and unbreakable. For example, the barrier film 200 may be configured by cyclo olefin polymer (COP), but is not limited thereto and may also be configured by a material such as polyimide (PI), poly carbonate (PC), and polyethylene terephthalate (PET).

An adhesive layer which bonds the display panel 120 and the barrier film 200 may be disposed between the display panel 120 and the barrier film 200.

The polarizer 210 is disposed on the barrier film 200. The polarizer 210 is a configuration which suppresses external light incident onto the display device 100 from being reflected to be visible. The polarizer 210 may be formed with a structure in which a plurality of layers is laminated.

An adhesive layer which bonds the barrier film 200 and the polarizer 210 is disposed between the barrier film 200 and the polarizer 210.

In the meantime, among the configurations of the display unit DP, a pad area of the display panel 120, a GIP area at the outside of the encapsulation substrate 125, the plurality of flexible films 130, and the printed circuit board 140 are vulnerable to the external shocks and are easily damaged by the shocks. Therefore, the display device 100 includes a configuration which protects the pad area of the display panel 120, the GIP area, the plurality of flexible films 130, and the printed circuit board 140 and suppresses the crack of the display unit DP.

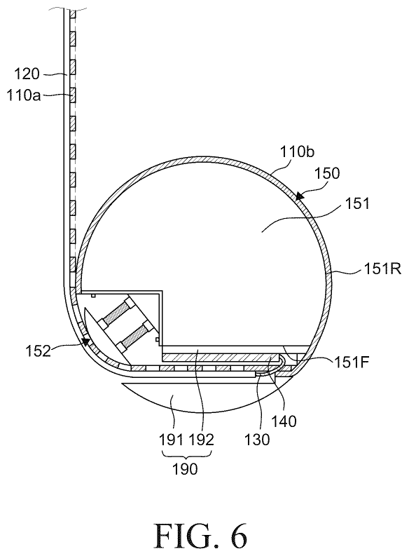

As illustrated in FIG. 6, as a configuration for suppressing the crack of the display unit DP, the cover unit 190 is disposed so as to enclose the pad area of the display panel 120, the plurality of flexible films 130, and the printed circuit board 140. The cover unit 190 may minimize shocks applied to the pad area of the display panel 120, the plurality of flexible films 130, and the printed circuit board 140 during a process of repeatedly winding and unwinding the display unit DP around and from the roller 151.

Further, the roller unit 150 includes a guide assembly 152 coupled to the roller 151 to minimize the damage caused by the pad area of the display panel 120 and the GIP area at the outside of the encapsulation substrate 125 which are bent during the process of winding and unwinding the display unit DP or the stress transmitted to the pad area or the GIP area caused by a part of the display panel 120 which is excessively bent.

Hereinafter, a cover unit 190 and a roller unit 150 of a display device 100 according to an exemplary embodiment of the present disclosure will be described in more detail with reference to FIG. 6.

FIG. 6 is a side surface view of a display device according to an exemplary embodiment of the present disclosure.

Referring to FIG. 6, a cover unit 190 is disposed to accommodate and protect a pad area of the display panel 120, the plurality of flexible films 130, and the printed circuit board 140. The cover unit 190 may maintain the pad area at one end of the display panel 120 and the printed circuit board 140 to be flat and protect the plurality of flexible films 130.

The cover unit 190 may include a front surface cover 191 and a rear surface cover 192.

The front surface cover 191 is disposed on one surface of the display panel 120. The front surface cover 191 is disposed so as to cover the pad area and the plurality of flexible films 130 of the non-active area NA of the display panel 120. The front surface cover 191 may be disposed not to cover the active area AA of the display panel 120, but to cover only the pad area which is the non-active area NA at one end of the display panel 120. If the front surface cover 191 also covers the active area AA, the images displayed in the active area AA may be blocked. Therefore, the front surface cover 191 may be disposed so as to overlap only the non-active area NA.

The front surface cover 191 is formed of a material having a rigidity so that when the display unit DP is wound, the front surface cover is not deformed and may protect the pad area at one end of the display panel 120 and the plurality of flexible films 130.

An outer side surface of the front surface cover 191 is formed to be convex to be connected to a curved surface portion of the roller 151 to form a round shape or a circular shape connected to the curved surface portion of the roller 151. That is, one surface of the front surface cover 191 may be formed as a curved surface. When the display unit DP is wound, the front surface cover 191 may form a round shape connected to the curved surface portion of the roller 151 or a circular shape connected to the curved surface portion of the roller 151.

The rear surface cover 192 may have a plate shape and may be coupled to the flat surface portion 151F of the roller 151.

The display panel 120 connected to the roller 151 by means of the second back cover 110b is wound around the roller 151 or unwound from the roller 151 in accordance with rotation of the roller 151. An end portion of the second back cover 110b may be connected to an outer circumferential surface of the roller 151. For example, a fastening member which passes through the second fastening hole AH2 provided at the other end of the second back cover 110b and the roller 151 is disposed to connect the second back cover 110b to the roller 151. Even though in FIG. 6, it is illustrated that an end of the second back cover 110b is connected onto the curved surface portion 151R of the roller, the end of the second back cover 110b may also be connected onto the flat surface portion 151F of the roller 151, it is not limited thereto.

The roller unit 150 includes a roller 151 and a guide assembly 152 which is coupled to the roller 151 so as to support the display unit DP.

The roller 151 includes a flat surface portion 151F and a curved surface portion 151R. A roller groove 151A is disposed between the flat surface portion 151F and the curved surface portion 151R and a support unit 151S is provided in the roller groove 151A to install the guide assembly 152. The support unit 151S includes a first support surface 151S1 and a second support surface 151S2. The first support surface 151S1 is connected to the flat surface portion 151F and the second support surface 151S2 is connected to the curved surface portion 151R. The first support surface 151S1 and the second support surface 151S2 are disposed to intersect each other. For example, the first support surface 151S1 and the second support surface 151S2 are disposed to vertically intersect each other, but are not limited thereto.

The flat surface portion 151F of the roller 151 is a portion around which the plurality of flexible films 130, the printed circuit board 140, and the pad area of the display panel 120, among the configurations of the display unit DP, are wound. The plurality of flexible films 130, the printed circuit board 140, and the pad area of the display panel 120 which are sound on the flat surface portion 151F may be supported by the flat surface portion 151F and the cover unit 190 to maintain a flat state at all times.

The curved surface portion 151R extends from the flat surface portion 151F. The curved surface portion 151R extends from one end of the flat surface portion 151F with a predetermined first curvature radius. Therefore, a part of the display unit DP which is wound on the curved surface portion 151R is bent with a first curvature radius.

If there are only the curved surface portion 151R and the flat surface portion 151F without the cover unit 190 and the guide assembly 152, a part of the display panel 120 is excessively bent at the boundary area between the curved surface portion 151R and the flat surface portion 151F to be curved. Specifically, an area between the curved surface portion 151R and the flat surface portion 151F is a low-curvature area with a small curvature radius and the display panel 120 which is wound between the curved surface portion 151R and the flat surface portion 151F is bent to have a small curvature radius to be easily damaged. In this case, a part of the display panel 120 adjacent to the pad area is repeatedly and excessively curved to affect the pad area and damage the pad area.

In the display device 100 according to the exemplary embodiment of the present disclosure, the cover unit 190 which supports the pad area of the display panel 120 and the printed circuit board 140 to be flat is disposed to minimize the damage of the display panel 120 and the printed circuit board 140.

Specifically, when the display unit DP is wound around the roller 151, the first back cover 110a and the second back cover 110b are wound while being bent in accordance with the shape of the roller 151. Further, the display panel 120 and the printed circuit board 140 are also wound while being bent in accordance with the shape of the roller 151. In the meantime, when the display unit DP is repeatedly wound and unwound, cracks may be highly likely to be caused in the vicinity of the edge of the display panel 120. Further, when the printed circuit board 140 which is formed of a rigid material is bent, the printed circuit board 140 may be broken. Therefore, the pad area of the display panel 120 and the printed circuit board 140 are disposed in the cover unit 190 formed of a material having a rigidity so that the pad area and the printed circuit board 140 may be maintained to be flat and protected.

Further, a part of the roller 151 around which the cover unit 190 is wound is formed to be flat so that the pad area, the printed circuit board 140, and the cover unit 190 are wound around the roller 151 while maintaining a flat state. Therefore, in the display device 100 according to the exemplary embodiment of the present disclosure, the cover unit 190 which supports the pad area and the printed circuit board 140 is disposed to maintain the pad area and the printed circuit board 140 to be flat and protect from the external shocks. Further, in the display device 100 according to the exemplary embodiment of the present disclosure, a flat surface portion is formed on an outer circumferential surface of the roller 151. Therefore, the pad area and the printed circuit board 140 are not bent and the damage of the display panel 120 and the printed circuit board 140 may be minimized.

Further, in the display device 100 according to the exemplary embodiment of the present disclosure, the guide assembly 152 is disposed between the curved surface portion 151R and the flat surface portion 151F of the roller 151 to minimize the display unit DP from being excessively bent to be damaged at the boundary area between the curved surface portion 151R and the flat surface portion 151F.

Hereinafter, a guide assembly 152 will be described in detail with reference to FIGS. 6 to 13.

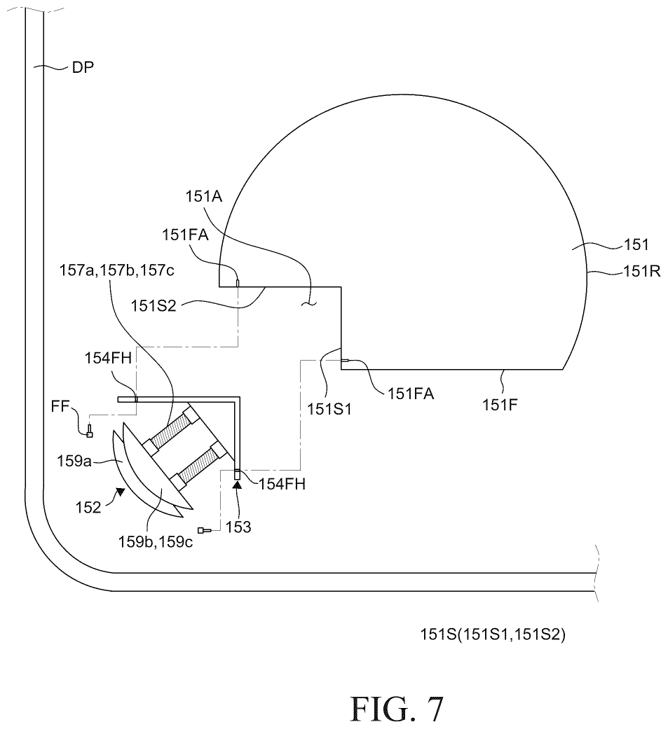

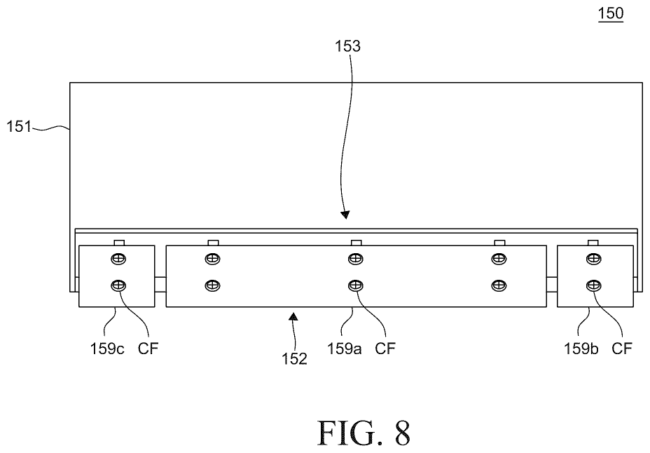

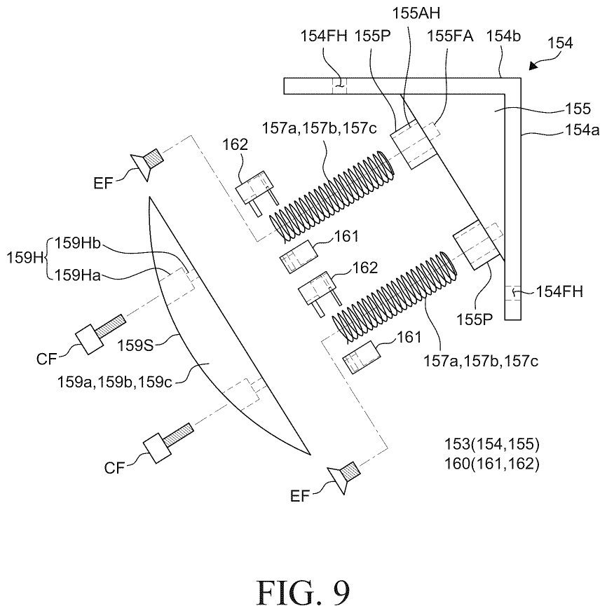

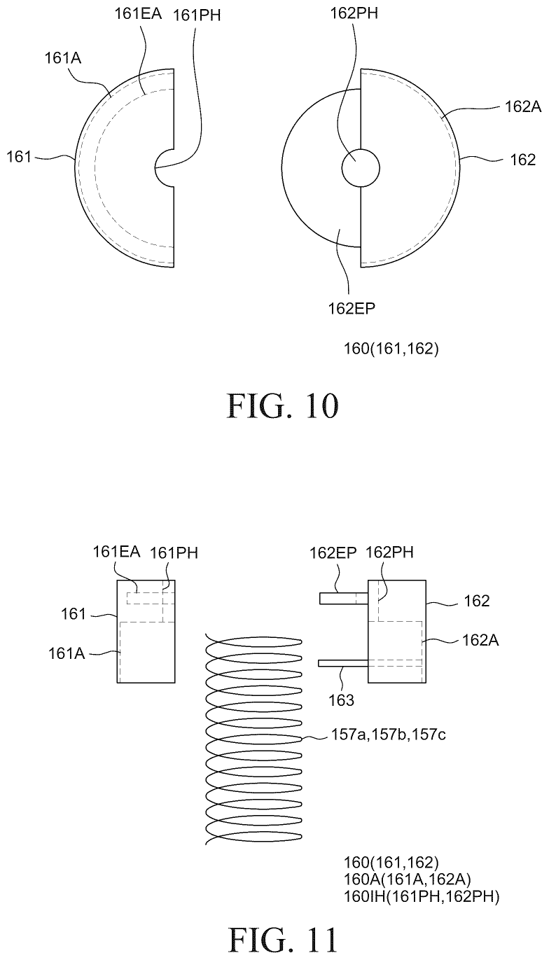

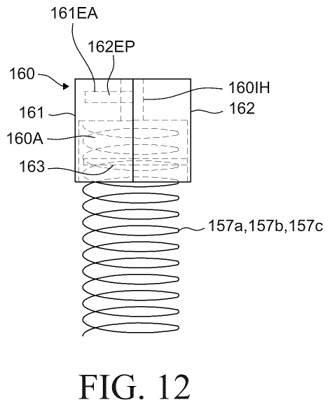

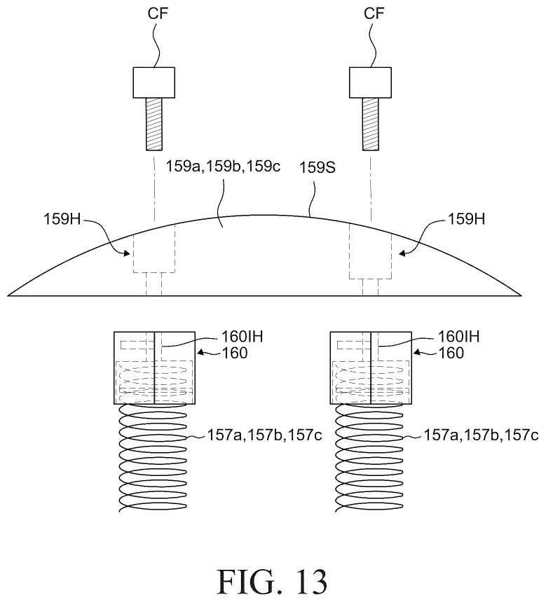

FIG. 6 is a side surface view of a display device according to an exemplary embodiment of the present disclosure. FIG. 7 is a side surface view illustrating that a roller unit of a display device according to an exemplary embodiment of the present disclosure is disassembled. FIG. 8 is a rear surface view of a roller unit of a display device according to an exemplary embodiment of the present disclosure. FIG. 9 is a side surface view illustrating that a guide assembly provided in a roller unit of a display device according to an exemplary embodiment of the present disclosure is disassembled. FIG. 10 is a rear surface view illustrating that a coupler provided in a roller unit of a display device according to an exemplary embodiment of the present disclosure is disassembled. FIG. 11 is a plan surface view illustrating that a coupler provided in a roller unit of a display device according to an exemplary embodiment of the present disclosure is disassembled. FIG. 12 is a view illustrating a coupled state of a coupler and an elastic member provided in a roller unit of a display device according to an exemplary embodiment of the present disclosure. FIG. 13 is a view illustrating a method of coupling a guide member and an elastic member provided in a roller unit of a display device according to an exemplary embodiment of the present disclosure.

Referring to FIGS. 6 to 13, the guide assembly 152 includes a frame 153 coupled to the roller 151, a plurality of elastic members 157a, 157b, and 157c coupled to the frame 153, and a plurality of guide members 159a, 159b, and 159c coupled to the plurality of elastic members 157a, 157b, and 157c to support the display unit DP.

The frame 153 includes a base frame 154 fixed to the roller 151 and a support frame 155 coupled to the base frame 154 to support the plurality of elastic members 157a, 157b, and 157c.

The base frame 154 is configured to be coupled to the support unit 151S of the roller 151. Specifically, the base frame 154 includes a first fixing unit 154a and a second fixing unit 154b which are disposed to intersect each other. For example, the first fixing unit 154a and the second fixing unit 154b may be disposed to vertically intersect each other, but are not limited thereto. The base frame 154 is fixed to the roller 151 such that the first fixing unit 154a is in contact with the first support surface 151S1 of the support unit 151S and the second fixing unit 154b is in contact with the second support surface 151S2 of the support unit 151S. The base frame 154 may be fixed to the roller 151 in various ways. For example, the base frame 154 may be fixed to the roller 151 by a frame fixing member FF which passes through a fixing hole 154FH provided in the fixing units 154a and 154b to inserted into the fixing groove 151FA provided on the fixing surfaces 151S1 and 151S2 of the roller 151, but is not limited thereto.

The support frame 155 has an inclined surface 155S obliquely disposed with the first fixing unit 154a and the second fixing unit 154b. A plurality of support protrusions 155P for supporting the plurality of elastic members 157a, 157b, and 157c is provided on the inclined surface 155S so as to protrude from the inclined surface 155S. An accommodation groove 155AH into which ends of the elastic members 157a, 157b, and 157c are inserted is provided in the support protrusion 155P. One ends of the elastic members 157a, 157b, and 157c are inserted into the accommodation groove 155AH to be supported by the support protrusion 155P to be erected against the inclined surface 155S. The support protrusion 155P vertically protrudes to the inclined surface 155S and the elastic members 157a, 157b, and 157c coupled to the support protrusion 155P may be disposed to be perpendicular to the inclined surface 155S. However, a placement angle of the support protrusion 155P with respect to the inclined surface 155S and a placement angle of the elastic members 157a, 157b, and 157c with respect to the inclined surface 155S are not limited thereto.

The plurality of support protrusions 155P is disposed to form a column along a length direction of the support frame 155 and may be disposed in a plurality of columns. However, the number and the placement of the support protrusions 155P are not limited thereto.

In addition to the shape illustrated, the frame 153 may be changed to various forms to be coupled to the support unit 151S of the roller 151 to support the plurality of elastic members 157a, 157b, and 157c. Further, a specific configuration of the support unit 151S provided in the roller 151 so as to allow the frame 153 to be coupled may be changed in various forms. For example, the support unit 151S may be formed in a shape including an inclined surface obliquely disposed between the flat surface portion 151F and the curved surface portion 151R of the roller 151, or a shape including a convex curved surface which connects the flat surface portion 151F and the curved surface portion 151R, or a shape including a concave curved surface which connects the flat surface portion 151F and the curved surface portion 151R, but is not limited thereto.

The plurality of elastic members 157a, 157b, and 157c is coupled to the roller 151 by means of the frame 153 to support the plurality of guide members 159a, 159b, and 159c. The plurality of elastic members 157a, 157b, and 157c is coupled to the plurality of support protrusions 155P provided in the frame 153 to be disposed in a column along the length direction of the roller 151 and may connect the support frame 155 and the guide members 159a, 159b, and 159c in the plurality of columns. However, the number and the placement of the elastic members 157a, 157b, and 157c are not limited thereto.

A plurality of elastic members 157a, 157b, and 157c is connected to the plurality of guide members 159a, 159b, and 159c respectively to allow the guide members 159a, 159b, and 159c to stably support the display unit DP. That is, one guide member may be supported by the plurality of elastic members. Hereinafter, it is separately described that among the plurality of guide members 159a, 159b, and 159c, a first guide member 159a supports a center portion of the display unit DP and a second guide member 159b and a third guide member 159c support both edge portions of the display unit DP. Further, it is separately described that among the plurality of elastic members 157a, 157b, and 157c, a first elastic member 157a supports the first guide member 159a, a second elastic member 157b supports the second guide member 159b, and a third elastic member 157c supports the third guide member 159c.

Each of the plurality of elastic members 157a, 157b, and 157c may be formed as a coil spring with one end which is coupled to the support unit 151S of the roller 151 by means of the frame 153 and the other end which is coupled to the guide members 159a, 159b, and 159c. However, the specific configuration of the elastic members 157a, 157b, and 157c may be changed in various forms.

As illustrated in FIG. 9, the elastic members 157a, 157b, and 157c may be fixed to the support frame 155 by an elastic member fastener EF which is fixed to the support frame 155. The elastic member fastener EF may be formed as a bolt, a pin, or other form which is configured to pressurize an end of the elastic members 157a, 157b, and 157c inserted into the accommodation groove 155AH of the support protrusion 155P toward the inclined surface 155S. A part of the elastic member fastener EF is inserted into the accommodation groove 155AH to be located into the elastic members 157a, 157b, and 157c so that the other part is inserted into a frame groove 155FA of the support frame 155 to fix the elastic members 157a, 157b, and 157c to the support frame 155. In addition, the elastic members 157a, 157b, and 157c may be fixed to the frame 153 in various manners.

The plurality of guide members 159a, 159b, and 159c is supported by the plurality of elastic members 157a, 157b, and 157c to elastically support the display unit DP. Each of the plurality of guide members 159a, 159b, and 159c has a contact surface 159S which is in contact with the display unit DP. The contact surface 159S is formed to have an outwardly convex arc shape to form a round shape together with the curved surface portion 151R of the roller 151 or form a circular shape together with the curved surface portion 151R of the roller 151.

The first guide member 159a, among the plurality of guide members 159a, 159b, and 159c is disposed so as to support a portion corresponding to the pixel unit 123 of the display panel 120 and the encapsulation substrate 125 which protects the pixel unit 123. Further, the second guide member 159b and the third guide member 159c are configured to support an outer portion of the encapsulation substrate 125 of the display panel 120. The second guide member 159b and the third guide member 159c have the same size and the first guide member 159a may be larger than the second guide member 159b and the third guide member 159c. Specifically, a width of the first guide member 159a may be larger than a width of the second guide member 159b and a width of the third guide member 159c. A width of the guide member refers to a width set based on a width direction of the display unit DP. The width of the first guide member 159a is larger so that the first elastic member 157a which supports the first guide member 159a may be disposed more than the second elastic member 157b which supports the second guide member 159b and the third elastic member 157c which supports the third guide member 159c.

The first guide member 159a is configured to support the display unit DP with a support force larger than that of the second guide member 159b and the third guide member 159c. That is, in the display device 100 according to the exemplary embodiment, a magnitude of the elastic force applied to the display unit DP through the first guide member 159a is set to be larger than a magnitude of the elastic force applied to the display unit DP through the second guide member 159b and a magnitude of the elastic force applied to the display unit DP through the third guide member 159c.

Generally, a strength of both edges of the display panel which is an outside area of the encapsulation substrate 125 is weaker than a strength of a center portion of the display panel 120 in which the encapsulation substrate 125 is disposed. Accordingly, when the display panel 120 is wound around the roller unit 150, a risk of a crack is relatively high in a GIP area at the outside of the encapsulation substrate 125. For this reason, the center portion of the display panel 120 is supported with a relatively large support force through the first guide member 159a and the edge portions of the display panel 120 are supported through the second guide member 159b and the third guide member 159c with a relatively small support force. By doing this, the stress distribution when the display panel 120 is wound is concentrated on the center portion of the display panel 120, and thus an impulsive force applied to the edge portion of the display panel 120 may be minimized.

Various methods may be used to set a support force with which the first guide member 159a supports the display unit DP and a support force with which the second guide member 159b and the third guide member 159c support both edge portions of the display unit DP to be different.

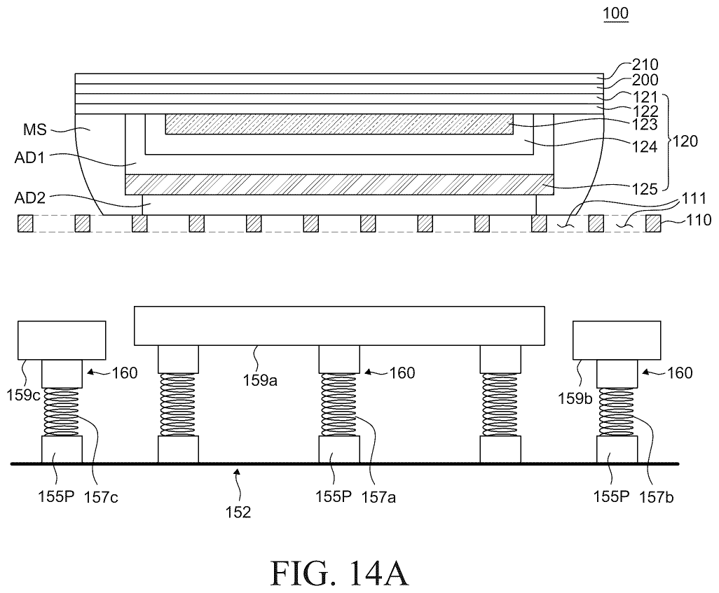

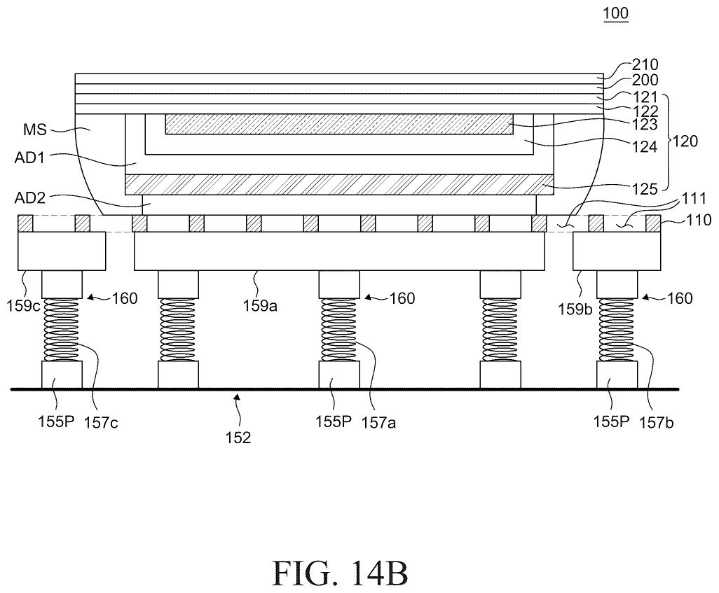

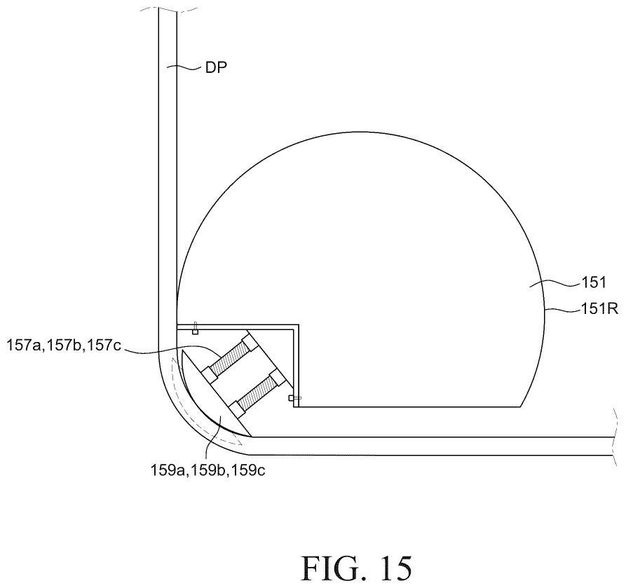

FIG. 14A is a view schematically illustrating a state that a roller unit of a display device according to an exemplary embodiment of the present disclosure is not in contact with a display unit. FIG. 14B is a view schematically illustrating a state that a roller unit of a display device according to an exemplary embodiment of the present disclosure is in contact with a display unit. FIG. 15 is a side surface view illustrating a state that a roller unit of a display device according to an exemplary embodiment of the present disclosure is in contact with a display unit.

As illustrated in FIGS. 7, 14A to 15, the effect as described above may be achieved by setting a length of the first elastic member 157a which supports the first guide member 159a to be longer than a length of the second elastic member 157b and a length of the third elastic member 157c which support the second guide member 159b and the third guide member 159c, respectively. When the length of the first elastic member 157a is set to be longer than the length of the second elastic member 157b and the length of the third elastic member 157c, the first guide member 159a may protrude from the roller 151 more than the second guide member 159b and the third guide member 159c. In this case, when the display unit DP is wound around the roller 151, the first guide member 159a is in contact with the display unit DP first so that the first elastic member 157a is elastically deformed and then the second guide member 159b and the third guide member 159c are in contact with the display unit DP. Therefore, the stress distribution may be concentrated on the center portion of the display panel 120 while supporting all the center portion and both edge portions of the display unit DP. Accordingly, the crack generated in the GIP area which is relatively weak may be effectively suppressed.

In addition, the lengths of the first elastic member 157a, the second elastic member 157b, and the third elastic member 157c are set to be equal to each other and a support height of the first elastic member 157a is set to be relatively high on the roller 151. By doing this, the first guide member 159a may protrude from the roller 151 more than the second guide member 159b and the third guide member 159c.

Further, a coil winding number of the first elastic member 157a is set to be larger than a coil winding number of the second elastic member 157b and a coil winding number of the third elastic member 157c. accordingly, a support force with which the first guide member 159a supports the display unit DP may be set to be larger than a support force with which the second guide member 159b and the third guide member 159c support both edge portions of the display unit DP.

The plurality of guide members 159a, 159b, and 159c may be coupled to the plurality of elastic members 157a, 157b, and 157c by means of the coupler 160. The coupler 160 may be fixed to the guide members 159a, 159b, and 159c by a coupler fixing member CF. To this end, a guide member hole 159H into which the coupler fixing member CF is inserted is provided in the guide members 159a, 159b, and 159c. The guide member hole 159H is provided so as to pass through the guide members 159a, 159b, and 159c in the thickness direction. The guide member hole 159H may include a first hole 159Ha provided to be exposed to the contact surface 159S and a second hole 159Hb which is coupled to the first hole 159Ha to be exposed to a surface to which the coupler 160 is coupled. A diameter of the second hole 159Hb is smaller than a diameter of the first hole 159Ha. The coupler fixing member CF has a part located in the first hole 159Ha and the other part which passes through the second hole 159Hb to be coupled to the coupler 160 to fix the coupler 160 to the guide members 159a, 159b, and 159c. In this case, the coupler fixing member CF is inserted into the guide member hole 159H so as not to protrude from surfaces of the guide members 159a, 159b, and 159c which are in contact with the display unit DP, that is, the contact surfaces 159S to be coupled to the coupler 160. In addition, the coupler 160 may be fixed to the guide members 159a, 159b, and 159c in various manners.

Referring to FIGS. 9 to 13, the coupler 160 includes a coupler groove 160A into which ends of the elastic members 157a, 157b, and 157c are inserted and an insertion hole 160IH into which the coupler fixing member CF is inserted. A part of the coupler fixing member CF which passes through the guide member holes 159H of the guide members 159a, 159b, and 159c may be inserted into the insertion hole 160IH. The coupler groove 160A is provided so as to be exposed from one end of the coupler 160 and the insertion hole 160IH may be provided so as to be exposed from the other end of the coupler 160.

The coupler 160 may be configured by a first body 161 and a second body 162. The first body 161 includes a first groove 161A which configures the coupler groove 160A, a first through hole 161PH which configures the insertion hole 160IH, and an engagement groove 161EA. The second body 162 includes a second groove 162A which configures the coupler groove 160A together with the first groove 161A, a second through hole 162PH which configures the insertion hole 160IH together with the first through hole 161PH, and an engagement protrusion 162EP which is inserted into the engagement groove 161EA. The engagement protrusion 162EP is formed in a semicircular shape protruding toward the first body 161 as illustrated in the drawing or other shape and the second through hole 162PH may be provided so as to pass through a part of the engagement protrusion 162EP. The first body 161 and the second body 162 may be coupled such that the engagement protrusion 162EP is inserted into the engagement groove 161EA.

A stopper 163 is provided in the second body 162 to fix the elastic members 157a, 157b, and 157c. The stopper 163 is formed to protrude toward the first body 161 to be fitted into an intermediate portion of the elastic members 157a, 157b, and 157c. The stopper 163 is inserted into the intermediate portion of the elastic members 157a, 157b, and 157c so that the elastic members 157a, 157b, and 157c inserted into the coupler groove 160A may be stably coupled to the stopper 163.

As illustrated in FIG. 11, the coupler 160 may be coupled to the elastic members 157a, 157b, and 157c as soon as the coupler is assembled. That is, the first body 161 and the second body 162 are placed to be opposite to each other with the elastic members 157a, 157b, and 157c therebetween so that the stopper 163 is fitted into the intermediate portion of the elastic members 157a, 157b, and 157c to assemble the coupler 160 coupled to the elastic members 157a, 157b, and 157c.

A specific configuration of the coupler 160 is not limited to those illustrated in the drawing. Further, a coupling method of the coupler 160 and the elastic members 157a, 157b, and 157c may be changed in various forms.

Further, in the display device 100 according to the exemplary embodiment of the present disclosure, the guide assembly 152 which supports the display unit DP is disposed between the curved surface portion 151R and the flat surface portion 151F of the roller 151 to minimize the display unit DP from being excessively bent to be damaged in a low curvature area between the curved surface portion 151R and the flat surface portion 151F. The guide members 159a, 159b, and 159c which are in contact with the display unit DP are supported by the elastic members 157a, 157b, and 157c so that the guide assembly 152 may elastically support the display unit DP when the display unit DP is wound around the roller 151. Accordingly, the display unit DP may be wound around the roller 151 to have a gentle curvature radius so that the damage caused by a stress generated when the display unit DP is wound and such a stress which are transmitted to the pad area or the GIP area may be minimized.

Further, the display device 100 according to the exemplary embodiment of the present disclosure supports the center portion of the display unit DP with a strong elastic force using the first guide member 159a. Further, both edge portions of the display unit DP are supported with a relatively weak elastic force using the second guide member 159b and the third guide member 159c. Accordingly, the stress distribution is concentrated on the center portion of the display unit DP while supporting all the center portion and both edge portions of the display unit DP and a crack generated in the GIP area with a relatively weak strength may be effectively suppressed.

A specific configuration of the guide assembly 152 which supports the display unit DP coupled to the roller 151 is not limited to those illustrated, but may be changed in various forms. For example, in the drawing, it is illustrated that three guide members 159a, 159b, and 159c which are in contact with the display unit DP are provided, the number of guide members may vary. Further, the number, the placement, and shapes of the elastic members 157a, 157b, and 157c which is supported by the roller 151 to apply the elastic force to the guide members 159a, 159b, and 159c may vary. For example, the elastic member may be formed in another shape which may apply an elastic force to the guide member, other than the coil spring. Further, even though in the drawing, it is illustrated that the elastic members 157a, 157b, and 157c are coupled to the frame 153 which is coupled to the support unit 151S of the roller 151, the elastic members 157a, 157b, and 157c may be configured to be directly coupled to the support unit 151S.

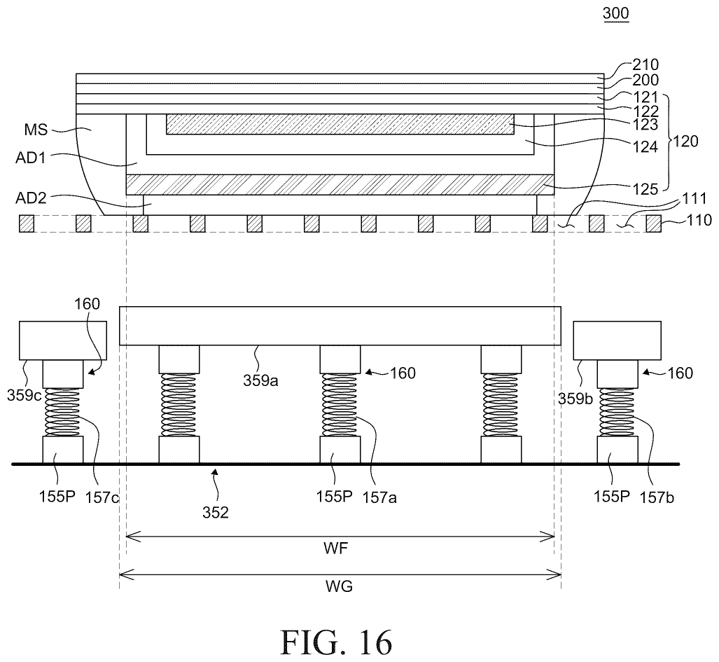

FIG. 16 is a view illustrating a display device according to another exemplary embodiment of the present disclosure. A display device 300 of FIG. 16 is substantially the same as the display device 100 of FIGS. 1 to 15 except for some configuration of a guide assembly 352, so that a redundant description will be omitted.

A guide assembly 352 includes a frame 153 coupled to the roller 151 (see FIG. 8), a plurality of elastic members 157a, 157b, and 157c coupled to the frame 153, and a plurality of guide members 359a, 359b, and 359c coupled to the plurality of elastic members 157a, 157b, and 157c to support the display unit DP. The plurality of guide members 359a, 359b, and 359c includes a first guide member 359a which supports a center portion of the display unit DP and a second guide member 359b and a third guide member 359c which support both edge portions of the display unit DP.

The first guide member 359a is disposed so as to support a portion corresponding to the pixel unit 123 of the display panel 120 and the encapsulation substrate 125 which protects the pixel unit 123. Further, the second guide member 359b and the third guide member 359c are configured to support an outer portion of the encapsulation substrate 125 of the display panel 120. The first guide member 359a is configured to support the display unit DP with an elastic force larger than that of the second guide member 359b and the third elastic member 359c. A width WG of the first guide member 359a is equal to or larger than a width WF of the encapsulation substrate 125. When the width WG of the first guide member 359a is smaller than a width WF of the encapsulation substrate 125, there is a problem in that a stress is excessively concentrated on a portion of the display unit DP supported by the first guide member 359a and an adjacent portion. However, when the width WG of the first guide member 359a is equal to or larger than a width WF of the encapsulation substrate 125, such a problem may be suppressed.

In the display device 300 according to the exemplary embodiment of the present disclosure, the guide assembly 352 supports the center portion of the display unit DP with a strong elastic force using the first guide member 359a. Further, the guide assembly 352 may support both edge portions of the display unit DP with a relatively weak elastic force through the second guide member 359b and the third guide member 359c. Accordingly, the stress distribution is concentrated on the center portion of the display panel 120 while supporting all the center portion and both edge portions of the display unit DP and a crack generated in the GIP area with a relatively weak strength may be effectively suppressed.

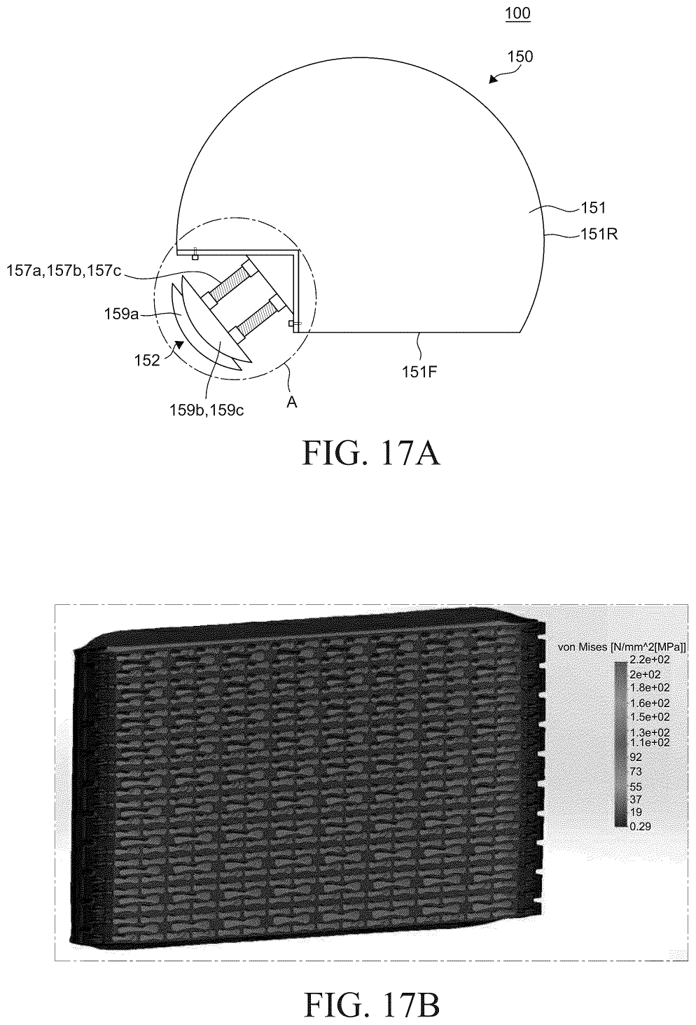

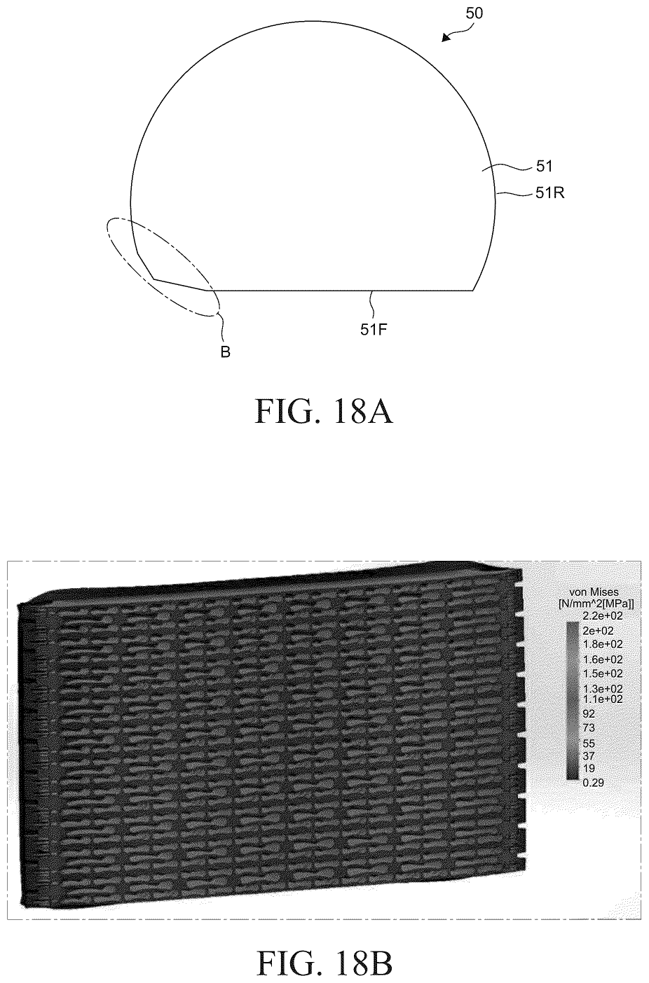

Hereinafter, an effect of reducing a stress of the display unit DP during a process of winding the display unit DP when guide assemblies 152 and 352 are disposed in the roller 151 as in the display devices 100 and 300 according to various exemplary embodiments of the present disclosure will be described with reference to FIGS. 17A to 18B.

FIG. 17A is a side surface view of a roller unit of a display device according to an exemplary embodiment. FIG. 17B is a simulation image illustrating a stress distribution applied to a display unit when a display unit of a display device according to an exemplary embodiment is wound around a roller unit. FIG. 18A is a side surface view of a roller unit of a display device according to a comparative embodiment. FIG. 18B is a simulation image illustrating a stress distribution applied to a display unit when a display unit of a display device according to a comparative embodiment is wound around a roller.

Referring to FIG. 17A, a roller unit 150 of a display device 100 according to the exemplary embodiment of the present disclosure includes a roller 151 and a guide assembly 152 disposed to support the display unit DP. The roller unit 150 is the same as illustrated in FIGS. 6 to 15 so that a detailed description thereof will be omitted.

In the simulation for the display device 100 of an exemplary embodiment illustrated in FIG. 17A, a first elastic member 157a which supports the guide member 159a which supports a center portion of the display unit DP is assumed as a coil spring with a length L1 of 25 mm and a coil winding number N1 of 15. Further, a second elastic member 157b and a third elastic member 157c which support the second guide member 159b and the third guide member 159c which support the edge portions of the display unit DP are assumed as coil springs with a length L2 of 15 mm and a coil winding number N2 of 10.

Referring to FIG. 18A, a roller unit 50 of a display device according to a comparative embodiment includes a roller 51 having a flat surface portion 51F and a curved surface portion 51R extending from the flat surface portion 51F. A low curvature area which does not have a configuration for supporting the display unit DP is formed between the flat surface portion 51F and the curved surface portion 51R of the roller 51.

In FIGS. 17B and 18B, a color of each area indicates a magnitude of a stress so that as an area is closer to blue, the stress to be applied is low and as an area is closer to red, the stress to be applied is high.

When the display unit DP is wound around the roller unit 150 of the display device 100 according to the exemplary embodiment, the display unit DP is supported by the guide assembly 152 in the boundary area A between the curved surface portion 151R and the flat surface portion 151F to be bent to have a relatively larger curvature radius to be wound. That is, the guide members 159a, 159b, and 159c of the guide assembly 152 may support the display unit DP to be wound with a larger curvature radius in the boundary area A between the curved surface portion 151R and the flat surface portion 151F.

Referring to FIG. 17B, a stress generated in the center portion of the display unit DP is approximately 60 Mpa and a stress generated in the edge portions of the display unit DP is approximately 40 Mpa. The display unit DP is supported by the plurality of guide members 159a, 159b, and 159c to be wound in the boundary area A between the curved surface portion 151R and the flat surface portion 151F of the roller 151 with a relatively larger curvature radius. Further, a center portion of the display unit DP is supported with a relatively larger support force by the first guide member 159a and both edge portions are supported with a relatively smaller support force by the second guide member 159b and the third guide member 159c. Therefore, it is confirmed that when the display unit DP is wound, the stress is relatively concentrated on the center portion and a relatively low stress is generated in both edge portions.

Referring to FIG. 18A, when the display unit DP is wound around a roller unit 50 of a display device according to a comparative embodiment, the display unit DP may be wound while being bent with a curvature radius smaller than the curvature radius of the curved surface portion 51R in a boundary area B between the curved surface portion 51R and the flat surface portion 51F. The boundary area B between the curved surface portion 51R and the flat surface portion 51F may be an area which is bent with a curvature radius smaller than a curvature radius of the curved surface portion 51R. Therefore, in the boundary area B, the display unit DP may be bent to have a curvature radius smaller than the curvature radius of the curved surface portion 51R.

Referring to FIG. 18B, a stress generated in the center portion of the display unit DP is approximately 60 Mpa and a stress generated in the edge portions of the display unit DP is approximately 100 Mpa. In the display device according to the comparative embodiment, the stress strength is increased from the center portion of the display unit DP to the edge portion so that a risk of the crack in the GIP area of the display unit DP is high.

The exemplary embodiments of the present disclosure can also be described as follows:

According to an aspect of the present disclosure, there is provided a display device. The display device includes a display unit. The display device further includes a roller in which the display unit is wound or unwound and a flat surface portion, a curved surface portion extending from the flat surface portion, and a support unit disposed between the flat surface portion and the curved surface portion are included. The display device further includes a guide member which is supported by the roller to support the display unit. The display device further includes an elastic member which is supported by the support unit to apply an elastic force to the guide member in a direction away from the roller to connect the roller and the guide member.

The elastic member may be coupled to a frame which is coupled to the support unit.

The support unit may include a first support surface and a second support surface which are disposed in a roller groove provided between the flat surface portion and the curved surface portion in an intersecting direction and the frame includes a first fixing unit fixed to the first support surface, a second fixing unit fixed to the second support surface, and a support frame which is connected to the first fixing unit and the second fixing unit to support the elastic member.

The support frame includes an inclined surface which is obliquely disposed with respect to the first fixing unit and the second fixing unit and the elastic member is disposed to be perpendicular to the inclined surface.

A support protrusion including an accommodation groove into which an end of the elastic member is inserted may be provided on the inclined surface to protrude from the inclined surface.

The elastic member may formed as a coil spring.

The elastic member may be fixed to the support frame by an elastic member fastener having a part located in the elastic member and the other part fixed to the support frame to pressurize an end of the elastic member to the inclined surface.

A plurality of elastic members may be disposed along a length direction of the roller in a column and may connect the roller and the guide member in a plurality of columns.

The display device may further include a coupler which is fixed to the guide member to connect the guide member and the elastic member.

The coupler may include a coupler groove into which an end of the elastic member is inserted and an insertion hole into which a part of a coupler fixing member which is coupled to the guide member to fix the coupler to the guide member is inserted.

The guide member may include a guide member hole provided to pass through the guide member in a thickness direction so that the coupler fixing member is inserted, and the coupler fixing member may be inserted into the guide member hole so as not to protrude from a contact surface provided in the guide member to be in contact with the display unit to be coupled to the coupler.

The coupler may include a first body having a first groove which configures the coupler groove and a first through hole which configures the insertion hole and a second body having a second groove which configures the coupler groove together with the first groove and a second through hole which configures the insertion hole together with the first through hole, and any one of the first body and the second body may include an engagement groove and the other includes an engagement protrusion inserted into the engagement groove.

The elastic member may be formed as a coil spring having one end supported by the roller and the other end inserted into the coupler groove, and the coupler may further include a stopper which is provided in any one of the first body and the second body to be inserted into an intermediate portion of the elastic member to fix the elastic member to the coupler.

The guide member may include: a first guide member configured to support a center portion of the display unit; and a second guide member and a third guide member disposed on both sides of the first guide member to support both edge portions of the display unit. And the elastic member may include: a first elastic member which is supported by the roller to apply an elastic force to the first guide member; a second elastic member which is supported by the roller to apply an elastic force to the second guide member; and a third elastic member which is supported by the roller to apply an elastic force to the third guide member.

A magnitude of the elastic force applied to the display unit by means of the first guide member may be set to be larger than a magnitude of the elastic force applied to the display unit by means of the second guide member and a magnitude of the elastic force applied to the display unit by means of the third guide member.

A length of the first elastic member may be longer than a length of the second elastic member and a length of the third elastic member.

The first elastic member, the second elastic member, and the third elastic member may be formed as coil springs, and a coil winding number of the first elastic member may be larger than a coil winding number of the second elastic member and a coil winding number of the third elastic member.

The display unit may include: a display panel which includes a pixel unit and an encapsulation substrate which protects the pixel unit; and a back cover which supports a rear surface of the display panel. And the first guide member may be configured to support a portion of the display unit corresponding to the encapsulation substrate and the second guide member and the third guide member may be configured to support an outer portion of the encapsulation substrate of the display unit.

A width of the first guide member may be equal to or larger than a width of the encapsulation substrate.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a display unit;
a roller is configured to wound or unwound the display unit and including a flat surface portion, a curved surface portion extending from the flat surface portion, and a support unit disposed between the flat surface portion and the curved surface portion;
a guide member supporting the display unit and is supported by the roller; and
an elastic member is configured to apply an elastic force to the guide member in a direction away from the roller to connect the roller and the guide member, and the elastic member is supported by the support unit.

2. The display device according to claim 1, wherein the elastic member is coupled to a frame coupled to the support unit.

3. The display device according to claim 2, wherein the support unit includes a first support surface and a second support surface which are disposed in a roller groove provided between the flat surface portion and the curved surface portion in an intersecting direction, and
the frame includes a first fixing unit fixed to the first support surface, a second fixing unit fixed to the second support surface, and a support frame connected to the first fixing unit and the second fixing unit to support the elastic member.

4. The display device according to claim 3, wherein the support frame includes an inclined surface obliquely disposed with respect to the first fixing unit and the second fixing unit, and
the elastic member is disposed to be perpendicular to the inclined surface.

5. The display device according to claim 4, wherein a support protrusion including an accommodation groove into which an end of the elastic member is inserted is provided on the inclined surface to protrude from the inclined surface.

6. The display device according to claim 5, wherein the elastic member is formed as a coil spring.

7. The display device according to claim 6, wherein the elastic member is fixed to the support frame by an elastic member fastener having a part located in the elastic member and the other part fixed to the support frame to pressurize an end of the elastic member to the inclined surface.

8. The display device according to claim 1, wherein a plurality of elastic members is disposed along a length direction of the roller in a column and connects the roller and the guide member in a plurality of columns.

9. The display device according to claim 1, further comprising:
a coupler fixed to the guide member to connect the guide member and the elastic member.

10. The display device according to claim 9, wherein the coupler includes:
a coupler groove into which an end of the elastic member is inserted; and
an insertion hole into which a part of a coupler fixing member which is coupled to the guide member to fix the coupler to the guide member is inserted.

11. The display device according to claim 10, wherein the guide member includes a guide member hole provided to pass through the guide member in a thickness direction so that the coupler fixing member is inserted, and
the coupler fixing member is inserted into the guide member hole so as not to protrude from a contact surface provided in the guide member to be in contact with the display unit to be coupled to the coupler.

12. The display device according to claim 10, wherein the coupler includes:
a first body having a first groove which configures the coupler groove and a first through hole which configures the insertion hole; and
a second body having a second groove which configures the coupler groove together with the first groove and a second through hole which configures the insertion hole together with the first through hole, and
any one of the first body and the second body includes an engagement groove and the other includes an engagement protrusion inserted into the engagement groove.

13. The display device according to claim 12, wherein the elastic member is formed as a coil spring having one end supported by the roller and the other end inserted into the coupler groove, and
the coupler further includes a stopper which is provided in any one of the first body and the second body to be inserted into an intermediate portion of the elastic member to fix the elastic member to the coupler.

14. The display device according to claim 1, wherein the guide member includes:
a first guide member configured to support a center portion of the display unit; and
a second guide member and a third guide member disposed on both sides of the first guide member to support both edge portions of the display unit, and
the elastic member includes:
a first elastic member which is supported by the roller to apply an elastic force to the first guide member;
a second elastic member which is supported by the roller to apply an elastic force to the second guide member; and
a third elastic member which is supported by the roller to apply an elastic force to the third guide member.

15. The display device according to claim 14, wherein a magnitude of the elastic force applied to the display unit by means of the first guide member is set to be larger than a magnitude of the elastic force applied to the display unit by means of the second guide member and a magnitude of the elastic force applied to the display unit by means of the third guide member.

16. The display device according to claim 15, wherein a length of the first elastic member is longer than a length of the second elastic member and a length of the third elastic member.

17. The display device according to claim 15, wherein the first elastic member, the second elastic member, and the third elastic member are formed as coil springs, and
a coil winding number of the first elastic member is larger than a coil winding number of the second elastic member and a coil winding number of the third elastic member.

18. The display device according to claim 14, wherein the display unit includes:
a display panel including a pixel unit and an encapsulation substrate which protects the pixel unit; and
a back cover supporting a rear surface of the display panel, and
the first guide member is configured to support a portion of the display unit corresponding to the encapsulation substrate, and the second guide member and the third guide member are configured to support an outer portion of the encapsulation substrate of the display unit.

19. The display device according to claim 18, wherein a width of the first guide member is equal to or larger than a width of the encapsulation substrate.
